(19) United States
(12) Patent Application Publication
(10) Pub. No.: US 2009/0321880 A1
(43) Pub. Date: Dec. 31, 2009

(54) SEMICONDUCTOR DEVICE

(76) Inventor: Shigetaka Aoki, Niigata (JP)

Correspondence Address: MCDERMOTT WILL & EMERY LLP, 600 13TH STREET, NW, WASHINGTON, DC, 20005-3096, US

(21) Appl. No.: 12/391,939

(22) Filed: Feb. 24, 2009

(30) Foreign Application Priority Data
Jun. 27, 2008 (JP) 2008-168739

(51) Int. Cl. H01L 29/72

(52) U.S. Cl. 257/591; 257/E29.173

(57) ABSTRACT

A semicoductor device includes: a collector layer made of a first conductivity type semiconductor; an intrinsic base layer formed on the collector layer and including a second conductivity type monocrystalline silicon germanium layer; a base extraction electrode formed around the intrinsic base layer and including a second conductivity type polycrystalline silicon layer and a second conductivity type polycrystalline silicon germanium layer; and a first conductivity type emitter layer formed in an upper portion of the intrinsic base layer. A silicon layer is formed in the upper portion of the intrinsic base layer and the emitter layer includes an upper emitter region formed in an upper portion of the silicon layer and a lower emitter region formed below and in contact with the upper emitter region.

### CROSS-REFERENCE TO RELATED APPLICATION

This non-provisional application claims priority under 35 U.S.C. §119(a) of Japanese Patent Application No. 2008-168739 filed in Japan on Jun. 27, 2008, the entire contents of which are hereby incorporated by reference.

### BACKGROUND OF THE INVENTION

The present disclosure relates generally to semiconductor devices, particularly to semiconductor devices having a silicon-germanium (SiGe) heterojunction with an epitaxially grown base layer.

With the development of microprocessing and self-alignment technologies, improvement in capability of silicon bipolar transistors has been attempted. For higher performance, attention has been paid to an Epi-base structure including an epitaxially grown base layer.

Particularly in recent years, researches and developments have been conducted actively on SiGe heterojunction bipolar transistors (SiGe-HBT) using an epitaxially grown SiGe mixed crystal semiconductor as a base layer. Above all, a non-selective epitaxial growth technology for simultaneously growing a Si epitaxial film or a SiGe epitaxial film on a silicon layer and a Si or SiGe polycrystalline film on an insulating film made of an oxide or nitride film has been expected as a potential technology for improving the performance of the transistors. For example, Published Japanese Patent Applications Nos. 2002-289834, 05-175222 and 06-069434 disclose SiGe heterojunction bipolar transistors and manufacturing methods of the same.

FIGS. 9 and 10 show a typical sectional structure and an impurity concentration profile of a bipolar transistor manufactured by a conventional non-selective epitaxial growth technology.

The structure of the bipolar transistor manufactured by the non-selective epitaxial growth technology and a manufacturing method thereof will be explained below with reference to FIGS. 9 and 10.

First, as shown in FIG. 9, an N⁻-type epitaxial layer is formed as a collector layer 101 on an N⁺-type impurity layer 115 which is a buried layer formed on an upper portion of a P-type silicon (Si) semiconductor substrate 114. Then, shallow isolation regions 102 and deep isolation regions 116 are selectively formed.

Then, a first silicon oxide film 118 is deposited by chemical vapor deposition (CVD) on the collector layer 101 and the isolation regions 102. A base opening A is selectively formed in part of the deposited first silicon oxide film 118 corresponding to a base formation region.

Then, a SiGe epitaxial film 103 is formed on the collector layer 101 and the isolation regions 102 exposed in the base opening A by, for example, electron beam epitaxy (MBE). The SiGe epitaxial film 103 is a layered structure including a non-doped Si buffer layer 103a, a P-type SiGe layer 103b and a non-doped Si-Cap layer 103c formed in this order on the collector layer 101. As shown in FIG. 10, the P-type SiGe layer 103b is doped with boron (B) at a concentration of about 1×10¹⁸ cm⁻³ to 5×10¹⁹ cm⁻³ and has a Ge gradient composition structure in which the Ge concentration is decreasing from the collector layer 101 to the Si-Cap layer 103c. For example, the non-doped Si buffer layer 103a may be 10 nm in thickness. The P-type SiGe layer 103b may have a peak Ge concentration value of 20 atom % and a thickness of 20 nm, for example. The non-doped Si-Cap layer 103c may be 20 nm in thickness, for example. By using the non-selective epitaxial growth technology, the monocrystalline SiGe epitaxial film 103 grows on the collector layer 101 and simultaneously, a polycrystalline base extraction electrode 104 grows on the isolation regions 102 made of silicon oxide.

A second silicon oxide film 105 is deposited on the whole surfaces of the SiGe epitaxial film 103 and the base extraction electrode 104, and an emitter opening B is selectively formed in part of the deposited second silicon oxide film 105 corresponding to an emitter formation region.

Then, an N-type polysilicon film is deposited on the second silicon oxide film 105 including the emitter opening B and patterned to form an emitter electrode 107.

The base extraction electrode 104 is patterned, and then thermal treatment such as rapid thermal annealing (RTA) is performed to allow solid phase diffusion of N-type impurities contained in the emitter electrode 107 to the SiGe epitaxial film 103 as an intrinsic base layer through the emitter opening B to form an emitter layer 108. Thus, an emitter-base junction is formed. In this process, as shown in FIG. 10, a PN junction is formed between the emitter layer 108 and the P-type SiGe layer 103b at an interface between the Si-Cap layer 103c and the P-type SiGe layer 103b.

Thereafter, sidewalls 110 are formed on the side surfaces of the emitter electrode 107 and the base extraction electrode 104 and a silicide layer 109 is formed in the top portions of the base extraction electrode 104 and the emitter electrode 107 in a self-alignment manner.

Then, an interlayer insulating film 111 is deposited to cover the whole surface of the semiconductor substrate 114 on which the silicide layer 109 has been formed. Contact plugs 112 are formed in the interlayer insulating film 111 so that they are electrically connected to the emitter electrode 107 and the base extraction electrode 104 through the silicide layer 109. Thereafter, metal wires 113 connected to the contact plugs 112 are formed on the interlayer insulating film 111. Thus, a SiGe-HBT shown in FIG. 9 is obtained.

The SiGe-HBT formed using the non-selective epitaxial growth technology as described above is advantageous in the following points: (1) since the polycrystalline film formed on the isolation regions 102 simultaneously with the SiGe epitaxial film 103 serving as the base layer is used as the base extraction electrode 104, a contact resistance at a contact between the SiGe epitaxial film 103 and the base extraction electrode 104 can be reduced, i.e., a base resistance can be reduced; and (2) the presence of the silicide layer 109 formed on the base extraction electrode 104 and the emitter electrode 107 in a self-alignment manner, particularly on the base extraction electrode 104, allows reduction of a base contact resistance, i.e., a base resistance.

As described above, the SiGe-HBT formed using the non-selective epitaxial growth technology reduces the base resistance and allows a dramatic improvement in high frequency characteristics, especially a maximum oscillatory frequency fmax, which is one of performance indices of transistor characteristics.

### SUMMARY OF THE INVENTION

However, the SiGe-HBT using the conventional non-selective epitaxial growth technology has the following drawbacks.

In the SiGe-HBT formed by the non-selective epitaxial growth technology, the SiGe epitaxial film 103 (the base layer) and the base extraction electrode 104 are formed simultaneously (integrally). Since the thickness of the SiGe epitaxial film 103 is determined at a designing stage, it is considerably difficult to form the base extraction electrode 104 thicker than the SiGe epitaxial film 103. For improving the performance of the bipolar transistor, thinning the base layer is particularly effective. Therefore, the thinner the base layer becomes, the thinner the base extraction electrode 104 becomes.

The silicide layer 109 is formed by silicidation between silicon and cobalt, i.e., by diffusing cobalt into silicon to cause a reaction with silicon. Therefore, in order to stabilize the contact resistance, a polycrystalline silicon layer having a thickness enough to form the silicide layer 109 is required. If the base extraction electrode 104 of the SiGe-HBT does not provide a sufficient amount of polycrystalline silicon necessary for the formation of the silicide layer 109, the silicidation proceeds in the SiGe epitaxial film 103 and is hindered by germanium (Ge). When the silicide layer 109 is formed thin to prevent the hindrance to the silicidation, the contact resistance may vary.

Thickening the Si-Cap layer 103c may be another possible technique. By this technique, the inhibition of the silicidation by Ge is avoided, and a sufficient amount of silicon necessary for the formation of the silicide layer 109 is supplied. Therefore, the contact resistance can be stabilized.

In this case, it is necessary to perform RTA at a high temperature to diffuse the impurities from the emitter electrode 107 for the purpose of reducing the width of the base layer as small as the base layer width achieved by the conventional method in which the Si-Cap layer 103c is not thickened. However, since the SiGe epitaxial film 103 has a warp at an interface with the collector layer 101 due to a lattice mismatch, lattice defects may occur when the warp is eased by RTA, and the transistor characteristics may deteriorate. For this reason, RTA cannot be performed at a sufficiently high temperature. Therefore, the thickening of the Si-Cap layer 103c results in the increase in width of the base layer and the deterioration of the high frequency characteristics.

As to the above-described conventional SiGe-HBT having the base layer and the base extraction electrode integrally formed by the non-selective epitaxial growth technology, thickening the base layer stabilizes the base contact resistance but deteriorates the high frequency characteristics. Further, thinning the base layer improves the high frequency characteristics but makes the silicide layer formed in the base extraction electrode, and the base contact resistance unstable. Thus, the conventional SiGe-HBT cannot combine excellent high frequency characteristics and a reduced base contact resistance.

The present disclosure intends to solve the above-described problem and to achieve both of the excellent high frequency characteristics and the stable low base contact resistance.

With the intention of solving the aforementioned problem, the present disclosure provides a semiconductor device including a thick silicon layer (a Si-Cap layer) formed in an upper portion of the base layer and an emitter layer of a double-layer structure in the silicon layer.

Specifically, the disclosed semiconductor device includes: a collector layer made of a first conductivity type semiconductor; an intrinsic base layer formed on the collector layer and including a second conductivity type monocrystalline silicon germanium layer; a base extraction electrode formed around the intrinsic base layer and including a second conductivity type polycrystalline silicon layer and a second conductivity type polycrystalline silicon germanium layer; and a first conductivity type emitter layer formed in an upper portion of the intrinsic base layer, wherein a silicon layer is formed in the upper portion of the intrinsic base layer and the emitter layer includes an upper emitter region formed in an upper portion of the silicon layer and a lower emitter region formed below and in contact with the upper emitter region.

Regarding the disclosed semiconductor device, even if the silicon layer is formed thick, the width of the base layer can be maintained almost equal to the conventional width without increasing the amount of thermal treatment. Therefore, a stable silicide layer can be formed on the base extraction electrode and excellent high frequency characteristics can be achieved. As a result, a base contact resistance can surely be reduced.

Regarding the disclosed semiconductor device, the collector layer has a first conductivity type retrograde region selectively formed in part of the collector layer below the emitter layer and having an impurity concentration increasing in a depth direction.

Regarding the disclosed semiconductor device, the silicon layer is preferably formed by non-doped epitaxial growth.

Regarding the disclosed semiconductor device, the emitter layer preferably has an impurity concentration profile having two peaks derived from the upper emitter region and the lower emitter region.

Regarding the disclosed semiconductor device, the silicon layer is preferably 50 nm or more in thickness.

Regarding the disclosed semiconductor device, the silicon layer is preferably 200 nm or less in thickness.

Regarding the disclosed semiconductor device, the base extraction electrode is preferably 80 nm or more in thickness.

Regarding the disclosed semiconductor device, the lower emitter region is preferably doped with arsenic impurities and the upper emitter region is preferably doped with phosphorus impurities.

As described above, the disclosed semiconductor device has the emitter layer of a double-layer structure. Therefore, the excellent high frequency characteristics can be achieved, and the stable silicide layer can be formed on the base extraction electrode. Thus, the base contact resistance can be stabilized.

### BRIEF DESCRIPTION OF THE DRAWINGS

FIG. 1 is a sectional view of a first example semiconductor device.

FIG. 2 is a graph of an impurity concentration profile of an emitter layer and an intrinsic base layer of the first example semiconductor device.

FIG. 3 is a plan view illustrating an emitter electrode, an emitter layer and a base extraction electrode of the first example semiconductor device.

FIGS. 4(a) to 4(e) are sectional views illustrating the processes of a method for manufacturing the first example semiconductor device.

FIGS. 5(a) to 5(c) are sectional views illustrating the processes of the method for manufacturing the first example semiconductor device.

FIG. 6 is a sectional view of a second example semiconductor device.

FIGS. 7(a) and 7(b) are sectional views illustrating the relevant processes of a method for manufacturing the second example semiconductor device.

FIG. 8 is a graph of an impurity concentration profile of an emitter layer, an intrinsic base layer and a collector layer of the second example semiconductor device.

FIG. 9 is a sectional view of a conventional SiGe heterojunction bipolar transistor (SiGe-HBT).

FIG. 10 is a graph of an impurity concentration profile of an emitter layer and an intrinsic base layer of the conventional SiGe-HBT.

### DETAILED DESCRIPTION OF THE INVENTION

### First Example Embodiment

A first example embodiment of the present disclosure will be described with reference to the drawings.

A first example semiconductor device has a relatively thick Si-Cap layer constituting an intrinsic base layer; and an emitter layer formed in the intrinsic base layer which includes a lower emitter region having a deep junction formed by ion implantation, and an upper emitter region having a shallow junction formed by impurity diffusion (solid phase diffusion) from an emitter electrode.

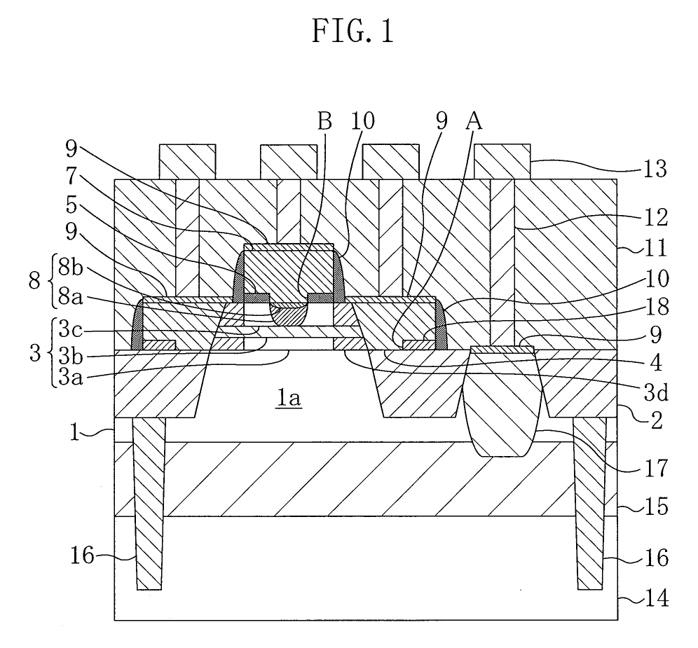

FIG. 1 shows the sectional structure of a SiGe heterojunction bipolar transistor (SiGe-HBT) as the first example semiconductor device.

As shown in FIG. 1, an N⁺-type impurity layer 15 which is a buried layer of about 500 nm in thickness formed on an upper portion of a P-type silicon (Si) semiconductor substrate 14. An N⁻-type epitaxial layer 1 of about 400 mn in thickness is formed on the N⁺-type impurity layer 15.

In the N⁻-type epitaxial layer, 1 first isolation regions (deep trenches) 16 penetrating the N⁻-type epitaxial layer 1 and the N⁺-type impurity layer 15 below the layer 1 are formed to define transistor formation regions. In an upper portion of the N⁻-type epitaxial layer 1, second isolation regions (shallow trenches) 2 are formed to define regions of collector layers 1a and regions of N⁺-type collector wall layers 17 in the N⁻-type epitaxial layer 1.

A monocrystalline SiGe epitaxial film 3 as an intrinsic base layer is formed on the collector layer 1a.

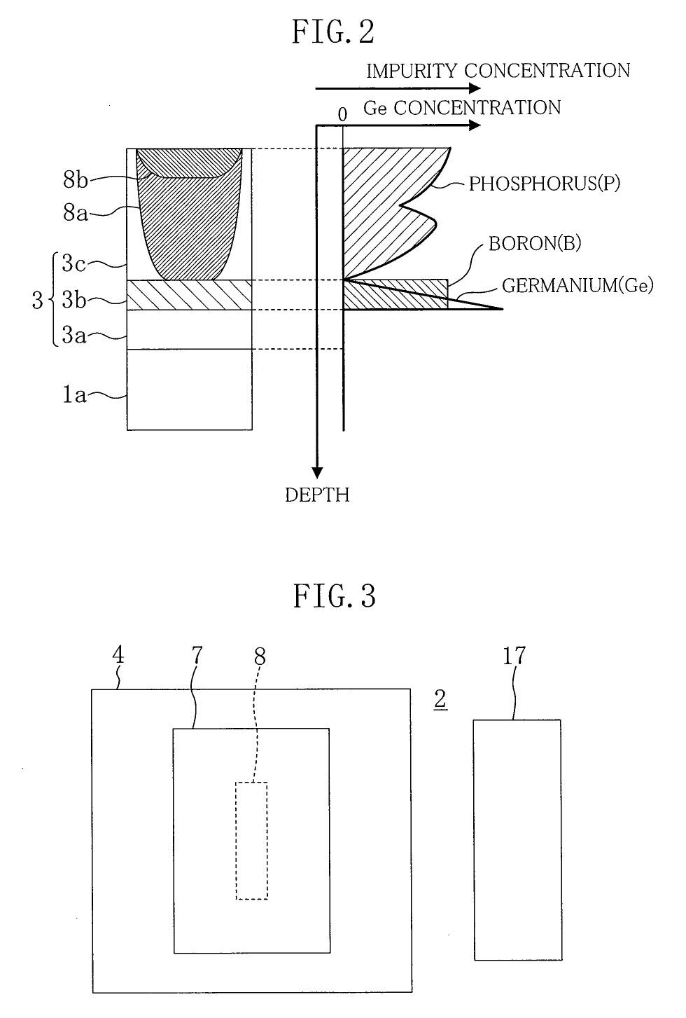

The SiGe epitaxial film 3 is a layered structure including a non-doped Si buffer layer 3a, a P-type SiGe layer 3b and a non-doped Si-Cap layer 3c grown in this order on the collector layer 1a. The P-type SiGe layer 3b is doped with boron (B) at a concentration of about 1×10¹⁸ cm⁻³ to 5×10¹⁹ cm⁻³, and has a Ge gradient composition structure in which the Ge concentration is decreasing from the collector layer 1a to the Si-Cap layer 3c as shown in an impurity concentration profile of FIG. 2.

The thicknesses of the Si buffer layer 3a, the P-type SiGe layer 3b and the Si-Cap layer 3c and the impurity concentration of the P-type SiGe layer 3b are determined based on an operating voltage and an operating frequency required by the transistors. For example, the Si buffer layer 3a may be 10 nm in thickness and the P-type SiGe layer 3b may have a peak Ge concentration value of 20 atom %, a thickness of 20 nm and a P-type impurity concentration of 1×10¹⁹ cm⁻³. The Si-Cap layer 3c may be 70 nm in thickness, for example.

An emitter electrode 7 made of N-type polysilicon doped with phosphorus (P) as N-type impurities is formed on the SiGe epitaxial film 3 with a second silicon oxide film 5 having an emitter opening B interposed therebetween.

As a feature of the first example embodiment, a lower emitter region 8a implanted with phosphorus (P) or arsenic (As) as the N-type impurities is formed in a lower portion of the emitter opening B in the Si-Cap layer 3c of the SiGe epitaxial film 3 to be in contact with the P-type SiGe layer 3b. An upper emitter region 8b to which phosphorus (P) doped in the emitter electrode 7 is solid-phase diffused is formed on the lower emitter region 8a. Thus, in the present embodiment, the lower emitter region 8a in contact with the P-type SiGe layer 3b and the upper emitter region 8b in contact with the emitter electrode 7 form an emitter layer 8.

An outer base region 3d integral with the SiGe epitaxial film 3 and made of monocrystalline silicon (partially SiGe) doped with boron is formed around the SiGe epitaxial film 3. Further, a base extraction electrode 4 integral with the SiGe epitaxial film 3 and made of polycrystalline silicon (partially SiGe) is formed around the outer base region 3d and on the second isolation region 2.

A first silicon oxide film 18 having a base opening A defining a base formation region remains around the base extraction electrode 4 and on the second isolation region 2.

Sidewalls 10 made of an insulating film of silicon oxide or the like are formed on the side surfaces of the base extraction electrode 4 and the emitter electrode 7.

A silicide layer 9 made of cobalt silicide (CoSi) or the like is formed in the top portions of the outer base region 3d, the base extraction electrode 4, the emitter electrode 7 and the collector wall layer 17. FIG. 3 shows the planar configuration (layout) of the second isolation region 2, the base extraction electrode 4, the emitter electrode 7, the emitter layer 8 and the collector wall layer 17.

An interlayer insulating film 11 made of silicon oxide or the like is formed on the whole surface of the semiconductor substrate 14 including the base extraction electrode 4 and the emitter electrode 7. Contact plugs 12 made of tungsten (W) or the like and electrically connected to the silicide layers 9 on the base extraction electrode 4, the emitter electrode 7 and the collector wall layer 17 are formed in the interlayer insulating film 11, and metal wires 13 connected to the contact plugs 12 are formed on the interlayer insulating film 11.

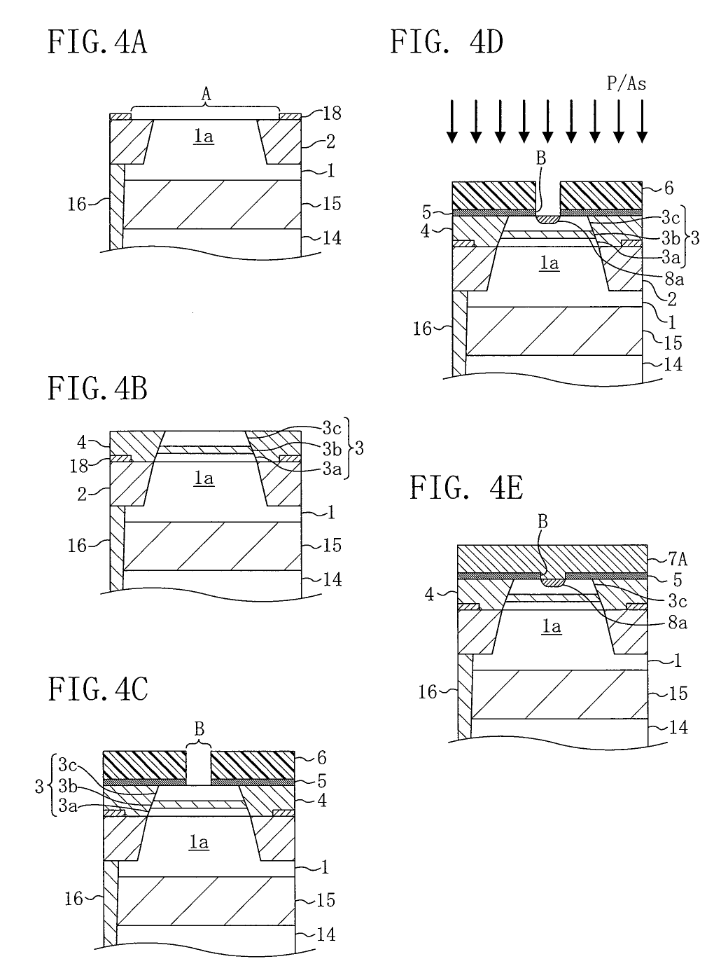

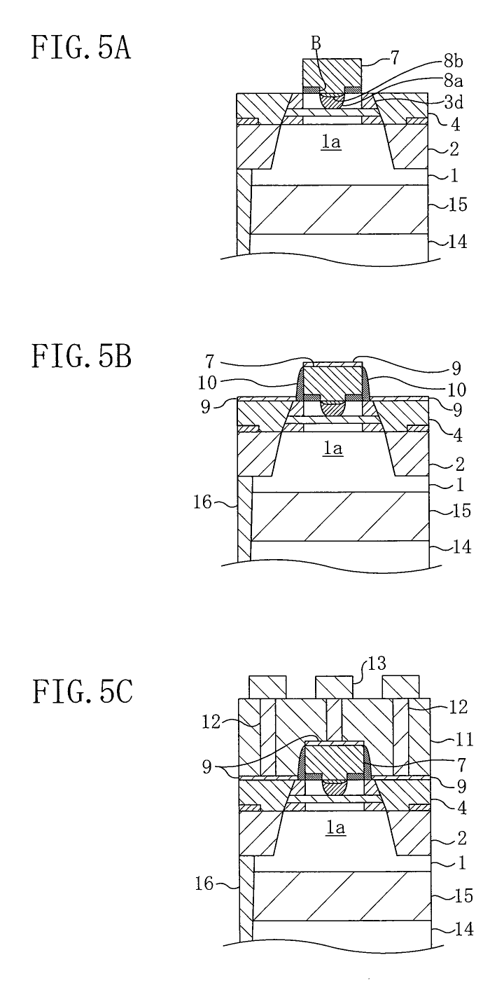

A method for manufacturing the thus-configured SiGe-HBT will be explained with reference to FIGS. 4(a)-4(e) and FIGS. 5(a)-5(c). Specifically, a method for forming a relevant part of the disclosed device, i.e., the collector layer 1a and the SiGe epitaxial film 3 formed thereon as the intrinsic base layer, the emitter layer 8 and the emitter electrode 7, will be explained below.

First, as shown in FIG. 4(a), an N⁻-type epitaxial layer 1 is formed on an N⁺-type impurity layer 15 which is a buried layer formed on an upper portion of a P-type silicon (Si) semiconductor substrate 14. Then, first isolation regions 16 and second isolation regions 2 are selectively formed by a trench formation technology and an oxide film embedding technology. In this way, a collector layer 1a surrounded by the isolation regions 2 is formed in the N⁻-type epitaxial layer 1.

Then, a first silicon oxide film 18 is deposited by CVD on the N⁻-type epitaxial layer 1 and the second isolation regions 2, and part of the first silicon oxide film 18 corresponding to the collector layer 1a is removed by lithography and wet etching to form a base opening A defining a base formation region.

Then, as shown in FIG. 4(b), a SiGe epitaxial film 3 is formed on the first silicon oxide film 18 and the second isolation region 2 and the collector layer 1a exposed in the base opening A of the first silicon oxide film 18 by electron beam epitaxy (MBE), ultrahigh vacuum (UHV)-CVD or low pressure (LP)-CVD. As described above, the SiGe epitaxial film 3 includes a non-doped Si buffer layer 3a, a P-type SiGe layer 3b and a non-doped Si-Cap layer 3c formed in this order on the collector layer 1a. By using a non-selective epitaxial growth technology, a monocrystalline epitaxial film (the SiGe epitaxial film 3) grows on the silicon collector layer 1a and a polycrystalline film (the base extraction electrode 4) grows on the second isolation region 2 and the first silicon oxide film 18.

Then, as shown in FIG. 4(c), a second silicon oxide film 5 is deposited by CVD on the SiGe epitaxial film 3 and the base extraction electrode 4. Then, using a resist pattern 6 formed by lithography and having an opening corresponding to an emitter formation region, the second silicon oxide film 5 is etched to form an emitter opening B defining the emitter formation region in the second silicon oxide film 5.

Then, as shown in FIG. 4(d), using the resist pattern 6 as a mask, phosphorus (P) or arsenic (As) ions are implanted into the Si-Cap layer 3c of the SiGe epitaxial film 3 to form an N-type lower emitter region 8a (a deep emitter layer).

As shown in FIG. 4(e), the resist pattern 6 is removed and an N-type polysilicon film 7A is deposited on the second silicon oxide film 5 including the emitter opening B.

Then, as shown in FIG. 5(a), using a resist pattern (not shown) as a mask, the deposited N-type polysilicon film 7A is patterned by lithography and etching to form an emitter electrode 7 made of the N-type polysilicon film 7A with outer base regions 3d left on both sides of the SiGe epitaxial film 3. Then, boron (B) ions are implanted to the base extraction electrode 4 and the outer base regions 3d by ion implantation using the resist pattern used for patterning the emitter electrode 7 as a mask. After the resist pattern is removed, the base extraction electrode 4 is patterned into a desired shape again by lithography and etching. Then, thermal treatment such as rapid thermal annealing (RTA) is performed for solid-phase diffusion of the N-type impurities (e.g., phosphorus) from the emitter electrode 7 through the emitter opening B formed in the second silicon oxide film 5 to the Si-Cap layer 3c of the SiGe epitaxial film 3 as the intrinsic base layer. In this way, an upper emitter region 8b is formed on the lower emitter region 8a. Optimization of the N-type impurity concentration in the emitter electrode 7 and conditions for RTA makes it possible to form the upper and lower emitter regions 8b and 8a partially overlapping each other.

Conditions for the ion implantation to the lower emitter region 8a may preferably be set so that the lower emitter region 8a and the P-type SiGe layer 3b form a PN junction at the interface between the non-doped Si-Cap layer 3c and the P-type SiGe layer 3b after the RTA. The Si-Cap layer 3c may be 70 nm in thickness. For example, a desired lower emitter region 8a can be formed by implanting phosphorus (P) ions at an acceleration energy of 20 keV and a dose amount of 5×10¹⁴ cm⁻². Since the emitter electrode 7 is doped with phosphorus (P) as the N-type impurities at a concentration of 5×10²⁰ cm⁻³, a desired upper emitter region 8b can be formed by RTA performed at 900° C. for 15 seconds.

In the first example embodiment, the ion implantation is performed after the removal of the second silicon oxide film 5. However, the ion implantation may be performed before the removal of the second silicon oxide film 5 to form the lower emitter region 8a.

Then, as shown in FIG. 5(b), an insulating film made of silicon oxide or the like is deposited to cover the whole surfaces of the patterned base extraction electrode 4 and the emitter electrode 7, and then the insulating film is etched back by dry etching to form sidewalls 10 made of the insulating film on the side surfaces of the emitter electrode 7 and the base extraction electrode 4. Subsequently, a silicide layer 9 is formed in the top portions of the base extraction electrode 4, the emitter electrode 7 and the collector wall layer (not shown) in a self-alignment manner by, for example, a salicide technology using cobalt (Co).

Then, as shown in FIG. 5(c), an interlayer insulating film 11 made of silicon oxide or the like is deposited to cover the whole surfaces of the base extraction electrode 4 and the emitter electrode 7 on which the silicide layer 9 has been formed. Then, contact holes are formed in the deposited interlayer insulating film 11 by lithography and dry etching so that the silicide layer 9 formed in the top portions of the base extraction electrode 4, the emitter electrode 7 and the collector wall layer is exposed. Tungsten or the like is filled in the contact holes by sputtering or CVD to form contact plugs 12. After that, metal wires 13 connected to the contact plugs 12 are formed on the interlayer insulating film 11. Thus, the SiGe-HBT shown in FIG. 1 is obtained.

In the first example embodiment, the Si-Cap layer 3c formed in an upper portion of the SiGe epitaxial film 3 as the intrinsic base layer of the SiGe-HBT is thick relative to the conventional one, and therefore the base extraction electrode 4 formed integral with the SiGe epitaxial film 3 becomes thick. As a result, a distance between the silicide layer 9 formed in the top portion of the base extraction electrode 4 and Ge doped in the base extraction electrode 4 is increased. Therefore, the silicide layer 9 of the base extraction electrode 4 can be formed thick and stable and a base contact resistance can be reduced and stabilized.

As described above, when the Si-Cap layer 103c of the conventional SiGe-HBT is made thick, it is necessary to increase the amount of thermal treatment for forming the emitter layer 108 by impurity diffusion from the emitter electrode 107 so as to reduce the width of the base layer as small as the conventional width and keep excellent current amplification factor and high frequency characteristics such as a maximum cutoff frequency and a maximum oscillatory frequency. However, if the amount of thermal treatment is increased in the conventional SiGe-HBT, the Ge profile may be deformed or crystal defects may occur to bring about deterioration of transistor characteristics.

In the first example embodiment, the emitter layer 8 includes two layers, i.e., the lower emitter region 8a formed by ion implantation through the emitter opening B and the upper emitter region 8b formed by impurity diffusion from the emitter electrode 7. This structure makes it possible to keep the width of the base layer almost equal to the conventionally employed width without increasing the amount of thermal treatment during the formation of the emitter layer 8. Therefore, the current amplification factor and the high frequency characteristics do not deteriorate.

When the double-layer emitter layer 8 is formed as described in the first example embodiment, an area of the side surfaces of the emitter layer 8 is increased. In general, the increase in side surface area of the emitter layer 8 brings about an increase in parasitic capacitance between the emitter and the base, and therefore deteriorates the high frequency characteristics. However, in the present embodiment, the Si-Cap layer 3c is a non-doped layer. That is, depletion layers are sufficiently formed on the side surfaces of the emitter layer 8 toward the Si-Cap layer 3c. Therefore, the parasitic capacitance between the emitter and the base is less likely to increase.

In the first example embodiment, the emitter layer 8 is formed by ion implantation and solid-phase diffusion from the emitter electrode 7. Therefore, as compared with the deep emitter layer (the lower emitter region 8a) formed only by the solid-phase diffusion from the emitter electrode 7, the emitter layer 8 can be reduced in impurity concentration. Therefore, the parasitic capacitance between the emitter and the base can be reduced to a further extent.

Since the upper emitter region 8b is formed by the solid-phase diffusion from the emitter electrode 7, an oxide film (a natural oxide film) on the surface of the Si-Cap layer 3c can satisfactorily be broken during the solid-phase diffusion of the N-type impurities. Therefore, an interface resistance (part of an emitter resistance) between the emitter layer 8 and the Si-Cap layer 3c can be reduced. As a result, the high frequency characteristics are less likely to deteriorate even when the interface resistance (the emitter resistance) is increased.

As shown in FIG. 2, the emitter layer 8 has an impurity concentration profile having two peaks. Therefore, both of the impurity concentration and the interface resistance of the emitter layer 8 can effectively be reduced.

In order to prevent the inhibition of the silicidation by Ge, the Si-Cap layer 3c is preferably 50 nm or more in thickness.

When the polysilicon base extraction electrode 4 is formed thick, differences in level in the SiGe-HBT (a level difference between the emitter electrode 7 and the collector wall layer 17 and between the base extraction electrode 4 and the collector wall layer 17) are increased. From the viewpoint of processing stability of the SiGe-HBT, the Si-Cap layer 3c is preferably 200 nm or less in thickness.

Conversely, when the base extraction electrode 4 is formed thin, surface morphology of the polysilicon base extraction electrode 4 deteriorates and the silicide layer 9 cannot be formed uniformly. From this viewpoint, the total thickness of the base extraction electrode 4 is preferably 80 nm or more.

In order to improve the performance of the SiGe-HBT, the lower emitter region 8a is preferably doped with arsenic (As) as the N-type impurities and the upper emitter region 8b is preferably doped with phosphorus (P) as the N-type impurities. By doping the lower emitter region 8a with arsenic impurities, the impurity concentration profile is less likely to become gentle even after the thermal treatment. Further, the polysilicon emitter electrode 7 can be doped with phosphorus at a higher concentration than arsenic. The higher the impurity concentration in the emitter electrode 7 is, the more the oxide film formed at the interface is likely to be broken, and the interface resistance can be reduced more effectively. Therefore, when the polysilicon emitter electrode 7 is doped with the phosphorus impurities, i.e., when the upper emitter region 8b is doped with the phosphorus impurities, the interface resistance between the emitter electrode 7 and the Si-Cap layer 3c can be reduced to a further extent.

According to the first example embodiment described above, the SiGe-HBT including the stable silicide layer 9 having a high cut-off frequency can be achieved without complicating the production processes.

### Second Example Embodiment

A second example embodiment of the present invention will be described below with reference to the drawings.

A second example semiconductor device includes, in addition to the same double-layer emitter layer 8 as that of the first example semiconductor device, a retrograde collector region formed in part of the collector layer 1a below the emitter layer 8.

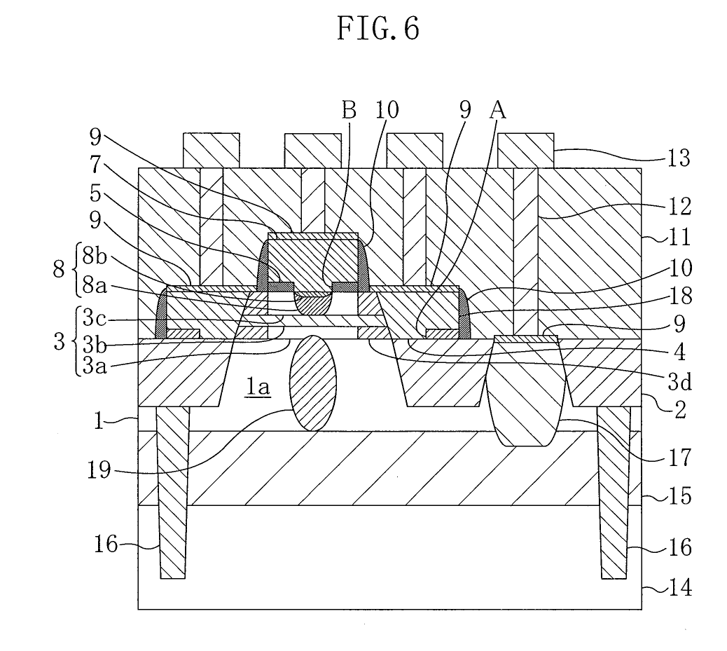

FIG. 6 shows the sectional structure of a SiGe heterojunction bipolar transistor (SiGe-HBT) as the second example semiconductor device. In FIG. 6, the same components as those shown in FIG. 1 are indicated by the same reference numerals to omit the explanation of them.

As shown in FIG. 6, the second example SiGe-HBT includes an N-type retrograde collector region 19 formed in part of the collector layer 1a below the emitter layer 8.

A method for manufacturing the retrograde collector region 19, which is a feature of the second example embodiment, will be explained below with reference to the drawings.

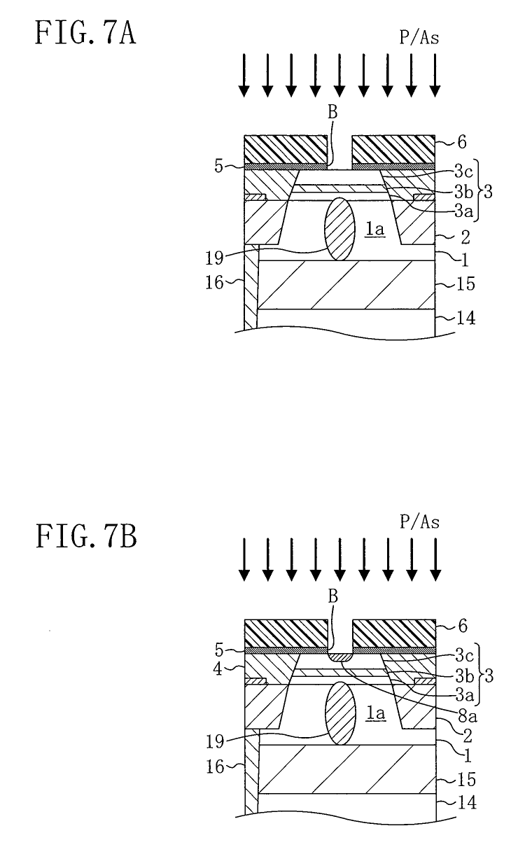

As shown in FIG. 7(a), a second silicon oxide film 5 is deposited by CVD, for example, on a SiGe epitaxial film 3 and a base extraction electrode 4 in the same manner as in the first example embodiment. Using a resist pattern 6 formed by lithography and having an opening corresponding to an emitter layer formation region as a mask, the second silicon oxide film 5 is etched to form an emitter opening B in the second silicon oxide film 5. Using the resist pattern 6 as a mask, phosphorus (P) or arsenic (As) is implanted by ion implantation to form a retrograde collector region 19. The ion implantation using phosphorus, for example, may be performed at an acceleration energy of 250 keV and a dose amount of 3×10¹³ cm⁻².

Then, as shown in FIG. 7(b), using the same resist pattern 6 as a mask, phosphorus (P) or arsenic (As) is implanted into a Si-Cap layer 3c of the SiGe epitaxial film 3 by ion implantation to form an N-type lower emitter region 8a (a deep emitter layer).

The subsequent processes are the same as those of the first example embodiment shown in FIG. 4(e) and FIGS. 5(a)-5(c). In this way, the SiGe-HBT shown in FIG. 6 is obtained.

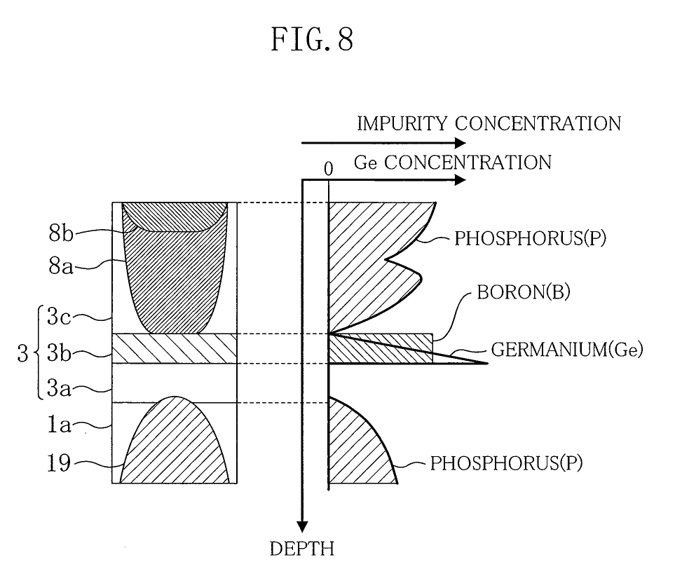

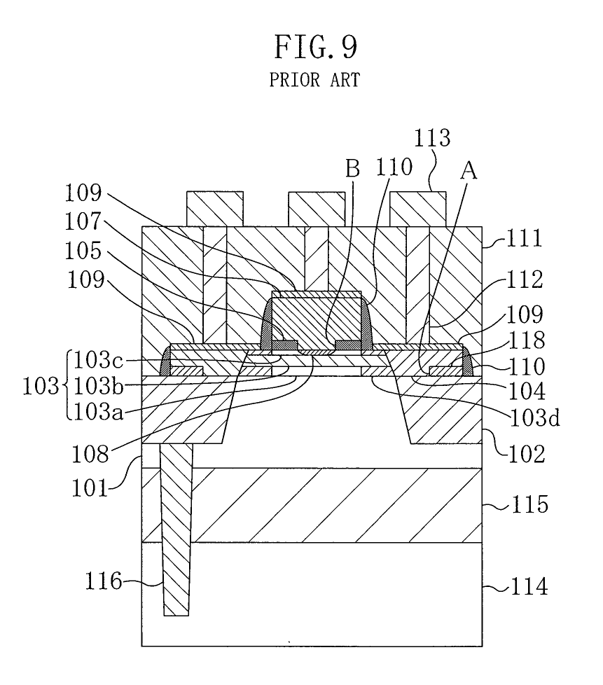

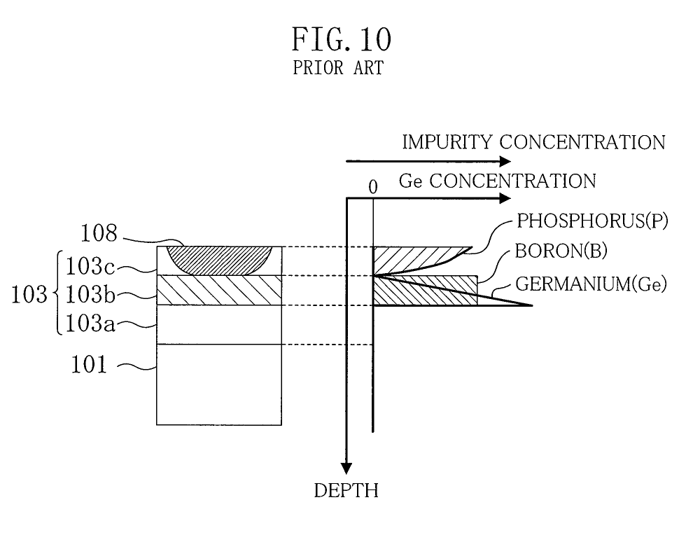

The SiGe epitaxial film 3 and the collector layer 1a of the second example SiGe-HBT formed by the foregoing method show the impurity concentration profile of FIG. 8.

As described above, the second example SiGe-HBT can be provided with the retrograde collector region 19 formed in the collector layer 1a in addition to the components described in the first example embodiment without any additional complicated production process.

According to the second example embodiment, the collector layer 1a includes the retrograde collector region. This configuration offers an advantage of the provision of the retrograde collector region 19, i.e., reduction of carrier transit time from the intrinsic base layer (the SiGe epitaxial film 3) to the collector layer 1a, in addition to the advantage of the first example embodiment. Therefore, the high frequency characteristics can be improved to a greater extent than in the first example SiGe-HBT. In other words, a high performance SiGe-HBT having excellent high frequency characteristics and the advantage of the first example embodiment can be obtained without complicating the production processes.

In the first and second example embodiments, the explanation is based on the NPN-type SiGe bipolar transistor. However, the present disclosure can be applied to PNP-type SiGe bipolar transistors.

As described above, the disclosed semiconductor device is able to achieve excellent high frequency characteristics and stabilize the base contact resistance. In particular, the present disclosure is useful for semiconductor devices having a SiGe heterojunction including an epitaxially grown base layer.

What is claimed is:

1. A semiconductor device comprising:
a collector layer made of a first conductivity type semiconductor;
an intrinsic base layer formed on the collector layer and including a second conductivity type monocrystalline silicon germanium layer;
a base extraction electrode formed around the intrinsic base layer and including a second conductivity type polycrystalline silicon layer and a second conductivity type polycrystalline silicon germanium layer; and
a first conductivity type emitter layer formed in an upper portion of the intrinsic base layer, wherein
a silicon layer is formed in the upper portion of the intrinsic base layer, and
the emitter layer includes an upper emitter region formed in an upper portion of the silicon layer, and a lower emitter region formed below and in contact with the upper emitter region.

2. The semiconductor device of claim 1, wherein
the collector layer has a first conductivity type retrograde region selectively formed in part of the collector layer below the emitter layer and having an impurity concentration increasing in a depth direction.

3. The semiconductor device of claim 1, wherein
the silicon layer is formed by non-doped epitaxial growth.

4. The semiconductor device of claim 1, wherein
the emitter layer has an impurity concentration profile having two peaks derived from the upper emitter region and the lower emitter region.

5. The semiconductor device of claim 1, wherein
the silicon layer is 50 nm or more in thickness.

6. The semiconductor device of claim 1, wherein
the silicon layer is 200 nm or less in thickness.

7. The semiconductor device of claim 1, wherein
the base extraction electrode is 80 nm or more in thickness.

8. The semiconductor device of claim 1, wherein
the lower emitter region is doped with arsenic impurities and the upper emitter region is doped with phosphorus impurities.
